(19) United States
(12) Patent Application Publication
(10) Pub. No.: US 2025/0389795 A1
(43) Pub. Date: Dec. 25, 2025

(54) METHOD FOR OPTIMIZING BROADBAND NOISE OF INDUCTIVE MAGNETIC FIELD SENSOR, AND MAGNETIC FIELD SENSOR

(71) Applicant: AEROSPACE INFORMATION RESEARCH INSTITUTE, CHINESE ACADEMY OF SCIENCES, Beijing (CN)

(72) Inventors: Guangyou FANG, Beijing (CN); Bin YAN, Beijing (CN); Wanhua ZHU, Beijing (CN); Leisong LIU, Beijing (CN)

(21) Appl. No.: 19/305,343

(22) Filed: Aug. 20, 2025

(30) Foreign Application Priority Data
Dec. 18, 2014 (CN) 202411864034.5

(51) Int. Cl. G01R 33/00

(52) U.S. Cl. CPC G01R 33/0011; G01R 33/0052

(57) ABSTRACT

The present disclosure provides a method for optimizing a broadband noise of an inductive magnetic field sensor as well as a magnetic field sensor, including: determining a functional relationship between an induced voltage of a coil and an effective permeability of a magnetic core of the inductive magnetic field sensor; determining an equivalent voltage noise expression of a temperature variation-induced permeability noise of the magnetic core according to the functional relationship; determining a key influencing factor of the magnetic core according to the equivalent voltage noise expression of the temperature variation-induced permeability noise of the magnetic core; modifying the magnetic core according to the key influencing factor of the magnetic core to optimize the temperature variation-induced permeability noise of the magnetic core; and constructing a dual-channel composite multi-stage modulation signal-noise separation circuit to optimize a low-frequency band noise and a high-frequency band noise of the inductive magnetic field sensor.

### CROSS-REFERENCE TO RELATED APPLICATION

This application claims the priority of Chinese Patent Application No. 202411864034.5 filed on Dec. 18, 2024 in the China National Intellectual Property Administration, the content of which is incorporated herein by reference in entirety.

### TECHNICAL FIELD

The present disclosure relates to fields of magnetic variable measurement and inductive magnetic field sensor technologies, and in particular to a method for optimizing a broadband noise of an inductive magnetic field sensor as well as a magnetic field sensor.

### BACKGROUND

An inductive magnetic field sensor is a type of sensor that may measure magnetic field changes using Faraday's law of electromagnetic induction. As one of the common magnetic field sensors, inductive magnetic field sensors have been widely applied in geophysics, medical treatment, national defense and other fields. In practical applications in geophysics, inductive magnetic field sensors have a measurement frequency range from 0.0001 Hz to 100 kHz, and may be applied in electromagnetic exploration instruments using magnetotelluric (MT) methods, controlled-source audio magnetotelluric (CSAMT) methods, transient electromagnetic (TEM) methods, etc.

In a process of achieving concepts of the present disclosure, it has been found through research that inductive magnetic field sensors in the related art are at least affected by high-frequency band noise and low-frequency band noise, which limits a working bandwidth of the magnetic field sensors.

### SUMMARY

In view of this, the present disclosure provides a method for optimizing a broadband noise of an inductive magnetic field sensor as well as a magnetic field sensor.

In an aspect of the present disclosure, a method for optimizing a broadband noise of an inductive magnetic field sensor is provided, including: determining a functional relationship between an induced voltage of a coil of the inductive magnetic field sensor and an effective permeability of a magnetic core of the inductive magnetic field sensor; determining an equivalent voltage noise expression of a temperature variation-induced permeability noise of the magnetic core according to the functional relationship; determining a key influencing factor of the magnetic core according to the equivalent voltage noise expression of the temperature variation-induced permeability noise of the magnetic core; modifying the magnetic core according to the key influencing factor of the magnetic core to optimize the temperature variation-induced permeability noise of the magnetic core; and constructing a dual-channel composite multi-stage modulation signal-noise separation circuit to optimize a low-frequency band noise and a high-frequency band noise of the inductive magnetic field sensor.

According to embodiments of the present disclosure, the determining a functional relationship between an induced voltage of a coil and an effective permeability of a magnetic core of the inductive magnetic field sensor includes: determining a functional relationship between the induced voltage of the coil and the effective permeability of the magnetic core in a time domain in a non-constant temperature environment, where a relative permeability of a magnetic core material changes slowly with temperature so that the effective permeability of the magnetic core changes with temperature, and the effective permeability of the magnetic core includes a direct current component and an alternating current component.

According to embodiments of the present disclosure, the determining an equivalent voltage noise expression of a temperature variation-induced permeability noise of the magnetic core according to the functional relationship includes: determining a noise term introduced by a temperature variation-induced permeability factor of the magnetic core in the functional relationship between the induced voltage of the coil and the effective permeability of the magnetic core; excluding a negligible term in the noise term introduced by the temperature variation-induced permeability factor of the magnetic core; and obtaining the equivalent voltage noise expression of the temperature variation-induced permeability noise of the magnetic core.

According to embodiments of the present disclosure, the functional relationship between the induced voltage of the coil and the effective permeability of the magnetic core of the inductive magnetic field sensor is expressed as:

$$\vec{e ( t )} = - [ \begin{matrix}NS {μ}_{appDC} \frac{d \vec{{B}_{AC}}}{dt} + \text{} NS \vec{{B}_{DC}} \frac{d {μ}_{appAC}}{dt} + \\ NS \frac{d ( \vec{{B}_{AC}} \times {μ}_{appAC} )}{dt} + NS \vec{{B}_{DC}} \frac{d {μ}_{appDC}}{dt}\end{matrix} ] ,$$

where μ_{appDC} represents a direct current component of the effective permeability, μ_{appAC} represents an alternating current component of the effective permeability, B_{DC} represents a direct current component of a magnetic flux intensity B, B_{AC} represents an alternating current component of the magnetic flux intensity B, N represents a number of turns of the coil, S represents a cross-sectional area of the coil and the magnetic core, and μₐₚₚ represents the effective permeability of the magnetic core.

According to embodiments of the present disclosure, the noise terms introduced by the temperature variation-induced permeability factor of the magnetic core in the expression of the functional relationship between the induced voltage of the coil and the effective permeability of the magnetic core include a second term

$$NS \vec{{B}_{DC}} \frac{d {μ}_{appAC}}{dt} ,$$

a third term

$$NS \frac{d ( \vec{{B}_{AC}} \times {μ}_{appAC} )}{dt} ,$$

and a fourth term

$$NS \vec{{B}_{DC}} \frac{d {μ}_{appDC}}{dt} ,$$

the alternating current component B_{AC} of the magnetic flux intensity is far less than the direct current component B_{DC} of the magnetic flux intensity and the direct current component μ_{appDC} of the effective permeability does not change over time so that the third term and the fourth term in the noise terms introduced by the temperature variation-induced permeability factor of the magnetic core are the negligible terms, and the equivalent voltage noise expression of the temperature variation-induced permeability noise of the magnetic core in a frequency domain is expressed as:

$${e}_{TC} ( f ) = \vert {NSB}_{DC} \times 2 π f {μ}_{appAC} ( f ) \vert ( V / \sqrt{Hz} ) ,$$

where f represents a frequency.

According to embodiments of the present disclosure, the alternating current component of the effective permeability is determined as the key influencing factor of the magnetic core according to the equivalent voltage noise expression of the temperature variation-induced permeability noise of the magnetic core, and the alternating current component of the effective permeability reflects a rate of change of magnetic permeability of the magnetic core with temperature.

According to embodiments of the present disclosure, the modifying the magnetic core according to the key influencing factor of the magnetic core includes: selecting a magnetic core made of a suitable material according to an application environment of the inductive magnetic field sensor; performing a vacuum magnetic-field annealing at a set temperature on the magnetic core while maintaining the effective permeability of the magnetic core to adjust an anisotropy of the magnetic core material and reduce internal structural defects, so as to reduce a rate of change of effective permeability of the magnetic core with temperature; and optimizing a magnetic circuit of the magnetic core by providing flat disk-shaped magnetic flux concentrators at both ends of the magnetic core, where centers of the magnetic flux concentrators are closely attached to both ends of the magnetic core to form a barbell shape as a whole.

According to embodiments of the present disclosure, the constructing a dual-channel composite multi-stage modulation signal-noise separation circuit to optimize a low-frequency band noise and a high-frequency band noise of the inductive magnetic field sensor includes: constructing a low-frequency channel to modulate a low-frequency component of a magnetic field signal to a frequency band away from a 1/f noise of an amplifier in the low-frequency channel, amplify the modulated magnetic field signal, demodulate the amplified magnetic field signal back to a low-frequency band and filter the demodulated magnetic field signal to achieve a signal-noise separation, so as to obtain the low-frequency component of the magnetic field signal; constructing a high-frequency channel to amplify the magnetic field signal and filter out a 1/f noise of an amplifier in the high-frequency channel, so as to obtain a high-frequency component of the magnetic field signal; and constructing a low-high frequency channel composite unit to integrate the low-frequency component and the high-frequency component of the magnetic field signal, so as to optimize the low-frequency band noise and the high-frequency band noise of the inductive magnetic field sensor.

In another aspect of the present disclosure, an inductive magnetic field sensor with broadband noise optimization is provided, including: a magnetic core, where the magnetic core has undergone vacuum magnetic-field annealing at a set temperature to adjust an anisotropy of a magnetic core material and reduce internal structural defects so as to reduce a rate of change of effective permeability of the magnetic core with temperature; a coil wound around a periphery of the magnetic core; and a dual-channel composite multi-stage modulation signal-noise separation circuit connected to the coil, including: a low-frequency channel configured to modulate a low-frequency component of a magnetic field signal to a frequency band away from a 1/f noise of an amplifier in the low-frequency channel, amplify the modulated low-frequency component, demodulate the amplified low-frequency component back to a low-frequency band and filter the demodulated low-frequency component to achieve a signal-noise separation, so as to obtain the low-frequency component of the magnetic field signal; a high-frequency channel arranged in parallel with the low-frequency channel, where the high-frequency channel is configured to amplify the magnetic field signal and filter out a 1/f noise of an amplifier in the high-frequency channel, so as to obtain a high-frequency component of the magnetic field signal; and a low-high frequency channel composite unit connected to the low-frequency channel and the high-frequency channel, where the low-high frequency channel composite unit is configured to integrate the low-frequency component and the high-frequency component of the magnetic field signal, so as to optimize a low-frequency band noise and a high-frequency band noise of the inductive magnetic field sensor.

According to embodiments of the present disclosure, the low-frequency channel includes a first modulation unit, a transformer, a first amplifier, a second modulation unit and a low-pass filter circuit unit, where: the first modulation unit is configured to modulate a low-frequency component of a received magnetic field signal to a frequency band away from a 1/f noise of the first amplifier; the transformer is configured to passively amplify the magnetic field signal modulated by the first modulation unit; the first amplifier is configured to further amplify the magnetic field signal amplified by the transformer; the second modulation unit is configured to demodulate the amplified magnetic field signal back to a low-frequency band and modulate the 1/f noise and a bias of the first amplifier to a high-frequency band; and the low-pass filter circuit unit is configured to filter out a high-frequency band noise interference; the high-frequency channel includes a high-pass filter composed of a third amplifier, a capacitor and a resistor connected in sequence, and the high-pass filter is configured to amplify the magnetic field signal and filter out a 1/f noise of the third amplifier in the high-frequency channel to obtain the high-frequency component of the magnetic field signal; and the low-high frequency channel composite unit includes a fourth amplifier, a capacitor and a plurality of resistors, a negative input terminal of the fourth amplifier is connected to a resistor, the capacitor and a resistor are connected in parallel between the negative input terminal and an output terminal of the fourth amplifier, and a positive input terminal of the fourth amplifier is connected to an output terminal of the low-frequency channel and an output terminal of the high-frequency channel through a resistor, so as to enable the low-high frequency channel composite unit to integrate the low-frequency component and the high-frequency component of the magnetic field signal to optimize the low-frequency band noise and the high-frequency band noise of the inductive magnetic field sensor.

According to embodiments of the present disclosure, a functional relationship between the induced voltage of the coil and the effective permeability of the magnetic core is determined, an equivalent voltage noise expression of the temperature variation-induced permeability noise of the magnetic core is determined according to the functional relationship, a key influencing factor of the magnetic core is determined according to the equivalent voltage noise expression of the temperature variation-induced permeability noise of the magnetic core, the magnetic core is modified according to the key influencing factor of the magnetic core to optimize the temperature variation-induced permeability noise of the magnetic core, and a dual-channel composite multi-stage modulation signal-noise separation circuit is constructed to optimize the low-frequency band noise and the high-frequency band noise of the inductive magnetic field sensor. As the magnetic core is modified according to the key influencing factor of the magnetic core, the rate of change of the effective permeability of the magnetic core with temperature may be reduced, so that the temperature variation-induced noise of the magnetic core may be reduced. Further, by constructing the dual-channel composite multi-stage modulation signal-noise separation circuit to separate the low-frequency band noise and the high-frequency band noise, the inductive magnetic field sensor may have characteristics of high sensitivity and low noise across a broad band and may be applied in a wider range of application scenarios.

### BRIEF DESCRIPTION OF THE DRAWINGS

Through the following description of embodiments of the present disclosure with reference to the accompanying drawings, the above and other objectives, features and advantages of the present disclosure may be more apparent. In the accompanying drawings:

FIG. 1 schematically shows a flowchart of a method for optimizing a broadband noise of an inductive magnetic field sensor according to embodiments of the present disclosure;

FIG. 2 schematically shows a comparison diagram of noise curves of an inductive magnetic field sensor according to embodiments of the present disclosure;

FIG. 3 schematically shows a schematic diagram of a long straight cylindrical magnetic core and a coil according to embodiments of the present disclosure;

FIG. 4 schematically shows variation curves of effective permeability corresponding to different length-to-diameter ratios of magnetic cores according to embodiments of the present disclosure;

FIG. 5 schematically shows a schematic diagram of a magnetic flux concentrator according to embodiments of the present disclosure;

FIG. 6 schematically shows a schematic dimensional diagram of a magnetic flux concentrator and a magnetic core according to embodiments of the present disclosure; and

FIG. 7 schematically shows a schematic circuit diagram of an inductive magnetic field sensor with broadband noise optimization according to embodiments of the present disclosure.

### DETAILED DESCRIPTION OF EMBODIMENTS

Embodiments of the present disclosure will be described below with reference to the accompanying drawings. However, it should be understood that these descriptions are merely exemplary and are not intended to limit the scope of the present disclosure. In the following detailed description, for ease of interpretation, many specific details are set forth to provide comprehensive understanding of embodiments of the present disclosure. However, it is clear that one or more embodiments may also be implemented without these specific details. In addition, in the following description, descriptions of well-known structures and technologies are omitted to avoid unnecessarily obscuring concepts of the present disclosure.

Terms are used herein for the purpose of describing specific embodiments only and are not intended to limit the present disclosure. The terms “including”, “containing”, etc. used herein indicate the presence of the feature, step, operation and/or component, but do not exclude the presence or addition of one or more other features, steps, operations or components.

All terms used herein (including technical and scientific terms) have the meanings generally understood by those skilled in the art, unless otherwise defined. It should be noted that the terms used herein shall be interpreted to have meanings consistent with the context of this specification, and shall not be interpreted in an idealized or overly rigid manner.

In a case of using the expression similar to “at least one of A, B and C”, it should be explained according to the meaning of the expression generally understood by those skilled in the art (for example, “a system including at least one of A, B and C” should include but not be limited to a system including A alone, a system including B alone, a system including C alone, a system including A and B, a system including A and C, a system including B and C, and/or a system including A, B and C).

In embodiments of the present disclosure, a collection, an update, an analysis, a processing, a use, a transmission, a provision, a disclosure, a storage, etc. of data involved (including but not limited to user personal information) comply with provisions of relevant laws and regulations, are used for legal purposes, and do not violate public order and good customs. In particular, necessary measures have been taken for user personal information to prevent unauthorized access to the user personal information data, so as to ensure security of user personal information as well as network security.

Inductive electromagnetic sensors have undergo many years of development, and there are relatively mature products in the related art.

For example, an inductive magnetic field sensor X1 covers a bandwidth ranging from 10⁻⁴ Hz to 104 Hz, where a noise level is 1.1 pT/√Hz at a frequency of 0.1 Hz, 0.11 pT/√Hz at a frequency of 1 Hz, and 0.02 pT/√Hz at a frequency of 10 Hz. The inductive magnetic field sensor X1 has a length of 1.2 m, a diameter of 75 mm, and a weight of about 9 kg. An inductive magnetic field sensor X2 covers a bandwidth ranging from 10⁻⁴ Hz to 103 Hz, where a noise level is 1 pT/√Hz at a frequency of 0.1 Hz, 0.1 pT/√Hz at a frequency of 1 Hz, and 0.01 pT/√Hz at a frequency of 100 Hz. The magnetic field sensor X2 has a length of 1.24 m, a diameter of 85 mm, and a weight of about 6.7 kg. An inductive magnetic field sensor X3 covers a bandwidth ranging from 10⁻⁵ Hz to 400 Hz, where a noise level is 1.5 pT/√Hz at a frequency of 0.1 Hz, 0.15 pT/√Hz at a frequency of 1 Hz, and 0.15 pT/√Hz at a frequency of 10 Hz. The magnetic field sensor X3 has a length of 0.95 m and a diameter of 60 mm.

Thus, the inductive magnetic field sensors in the related art have lengths ranging from about 1.2 m to 1.4 m and cover bandwidths ranging from 10⁻⁵ Hz to 104 Hz, but it is difficult to balance a low-frequency band and a high-frequency band. For example, the inductive magnetic field sensor X3 may cover a low frequency down to 10⁻⁵ Hz but a high frequency only up to 400 Hz, and the inductive magnetic field sensor X1 may cover a high frequency up to 104 Hz but a low frequency only down to 10⁻⁴ Hz.

A magnetic core is a magnetic flux concentration part of the inductive magnetic field sensor and also a key influencing factor for a noise level of the sensor. On the one hand, an initial permeability of a magnetic core material is affected by temperature and an additional low-frequency noise may be introduced, which limits a low-frequency working bandwidth of the sensor. On the other hand, a traditional inductive magnetic field sensor has a long rod-shaped magnetic core, and a magnetic core that is made of a soft magnetic material with the initial permeability of tens of thousands may have an effective permeability of only a few hundred due to an action of demagnetizing field. Therefore, in a case of a limited space, it is difficult to increase a length-to-diameter ratio of the magnetic core, resulting in an upper limit on the effective permeability of the magnetic core and an induced voltage of a probe.

In addition, for an inherent 1/f noise in the low-frequency band, it is typical to adopt auto-zero or chopping amplification technologies in the related art. An auto-zero amplifier has more in-band noise voltage than a standard operational amplifier, and it is needed to increase a sampling frequency to reduce a low-frequency noise voltage, which may lead to an additional charge injection. A chopper amplifier has a lower low-frequency noise voltage in its frequency band, but a large number of spike signals may be generated at a chopping frequency and its harmonics, which causes a large noise current in the high-frequency band.

In view of this, an embodiment of the present disclosure provides a method for optimizing a broadband noise of an inductive magnetic field sensor, including: determining a functional relationship between an induced voltage of a coil and an effective permeability of a magnetic core of the inductive magnetic field sensor; determining an equivalent voltage noise expression of a temperature variation-induced permeability noise of the magnetic core according to the functional relationship; determining a key influencing factor of the magnetic core according to the equivalent voltage noise expression of the temperature variation-induced permeability noise of the magnetic core; modifying the magnetic core according to the key influencing factor of the magnetic core to optimize the temperature variation-induced permeability noise of the magnetic core; and constructing a dual-channel composite multi-stage modulation signal-noise separation circuit to optimize a low-frequency band noise and a high-frequency band noise of the inductive magnetic field sensor.

Another embodiment of the present disclosure further provides an inductive magnetic field sensor with broadband noise optimization, including: a magnetic core, where the magnetic core has undergone vacuum magnetic-field annealing at a set temperature to adjust an anisotropy of a magnetic core material and reduce internal structural defects so as to reduce a rate of change of effective permeability of the magnetic core with temperature; a coil wound around a periphery of the magnetic core; and a dual-channel composite multi-stage modulation signal-noise separation circuit connected to the coil, including: a low-frequency channel configured to modulate a low-frequency component of a magnetic field signal to a frequency band away from a 1/f noise of an amplifier in the low-frequency channel, amplify the modulated magnetic field signal, demodulate the amplified magnetic field signal back to a low-frequency band and filter the demodulated magnetic field signal to achieve a signal-noise separation, so as to obtain the low-frequency component of the magnetic field signal; a high-frequency channel arranged in parallel with the low-frequency channel, where the high-frequency channel is configured to amplify the magnetic field signal and filter out a 1/f noise of an amplifier in the high-frequency channel, so as to obtain a high-frequency component of the magnetic field signal; and a low-high frequency channel composite unit connected to the low-frequency channel and the high-frequency channel, where the low-high frequency channel composite unit is configured to integrate the low-frequency component and the high-frequency component of the magnetic field signal, so as to optimize a low-frequency band noise and a high-frequency band noise of the inductive magnetic field sensor.

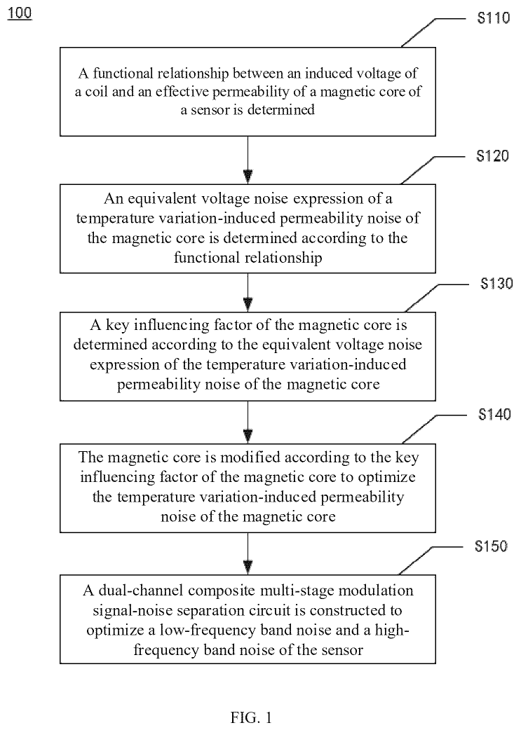

FIG. 1 schematically shows a flowchart of a method for optimizing a broadband noise of an inductive magnetic field sensor according to embodiments of the present disclosure.

As shown in FIG. 1, a method 100 includes operation S110 to operation S150.

In operation S110, a functional relationship between an induced voltage of a coil and an effective permeability of a magnetic core of a sensor is determined.

In operation S120, an equivalent voltage noise expression of a temperature variation-induced permeability noise of the magnetic core is determined according to the functional relationship.

In operation S130, a key influencing factor of the magnetic core is determined according to the equivalent voltage noise expression of the temperature variation-induced permeability noise of the magnetic core.

In operation S140, the magnetic core is modified according to the key influencing factor of the magnetic core to optimize the temperature variation-induced permeability noise of the magnetic core.

In operation S150, a dual-channel composite multi-stage modulation signal-noise separation circuit is constructed to optimize a low-frequency band noise and a high-frequency band noise of the sensor.

In addition to the temperature variation-induced permeability noise (TC noise) of the magnetic core, the inductive magnetic field sensor further includes other noise sources, such as a loss noise of magnetic core (RC noise), a thermal noise of coil resistance (TR noise), a 1/f noise of coil resistance (FR noise), an equivalent input voltage noise of circuit (CV noise), a voltage bias temperature drift noise of circuit (CT noise), an equivalent input current noise of circuit (CI noise), a feedback resistance noise (FB noise) and an attenuation resistance noise (TT noise). The inventors have proposed noise reduction and optimization on other noise sources, as described in patents such as CN202410607657.8 and CN202410776684.8, which mainly focus on researches and improvements on other noise sources. The present disclosure focuses on optimizing the TC noise, and achieves an inductive magnetic field sensor with improvement of full-band noise including low-frequency noise and high-frequency noise through a specially designed dual-channel composite multi-stage modulation signal-noise separation circuit.

According to embodiments of the present disclosure, based on Faraday's law of electromagnetic induction, an ideal induced voltage e(t) of the coil may be expressed by Equation (1).

$$e ( t ) = - N \frac{d Φ}{dt} = - {μ}_{app} NS \frac{dB}{dt} \qquad ( 1 )$$

where N represents the number of turns of the coil, Ø represents a magnitude of a magnetic flux passing through the coil, S represents an area of the coil and the magnetic core, μₐₚₚ represents an effective permeability of the magnetic core, which characterizes a degree to which the magnetic core concentrates the magnetic field, B represents a magnetic flux intensity, and/represents time.

In an ideal state, the number of turns N of the coil, the area S of the coil and the magnetic core, and the effective permeability μapp of the magnetic core do not change with the time t. Thus, the ideal induced voltage e(t) is uniquely proportional to a rate of change of the magnetic flux intensity B, and the induced voltage of the coil may be expressed by Equation (2).

$$\vec{e ( t )} = - N \frac{d \vec{Φ}}{dt} = - NS \frac{d ( {μ}_{app} \times \vec{B} )}{dt} \qquad ( 2 )$$

According to embodiments of the present disclosure, considering that a relative permeability of the magnetic core material changes slowly with temperature so that the effective permeability of the magnetic core also changes with temperature, and considering that the effective permeability of the magnetic core includes both a direct current (DC) component and an alternating current (AC) component, it is possible to determine a functional relationship between the induced voltage of the coil and the effective permeability of the magnetic core in a time domain in a non-constant temperature environment.

In most application environments, the relative permeability ur of the magnetic core material changes slowly with temperature, causing the effective permeability μapp of the magnetic core of the inductive magnetic field sensor to also change with temperature. Thus, in a non-constant temperature environment (which is typical in general applications), the effective permeability μapp has not only a DC component but also an AC component. Therefore, the functional relationship between the induced voltage of the coil and the effective permeability of the magnetic core may be expressed by Equation (3).

$$\vec{e ( t )} = - [ \begin{matrix}NS {μ}_{appDC} \frac{d \vec{{B}_{AC}}}{dt} + \text{} NS \vec{{B}_{DC}} \frac{d {μ}_{appAC}}{dt} + \\ NS \frac{d ( \vec{{B}_{AC}} \times {μ}_{appAC} )}{dt} + NS \vec{{B}_{DC}} \frac{d {μ}_{appDC}}{dt}\end{matrix} ] \qquad ( 3 )$$

where e̅(̅t̅)̅ represents an induced voltage of the coil considering a temperature variation as well as the DC component and the AC component of the effective permeability μₐₚₚ, μ_{appDC} represents the DC component of the effective permeability, μ_{appAC} represents the AC component of the effective permeability, B_{DC} represents a DC component of the magnetic flux intensity B, and B_{AC} represents an AC component of the magnetic flux intensity B, where μ_{appDC} and B_{DC} do not change with time.

According to embodiments of the present disclosure, determining the equivalent voltage noise expression of the temperature variation-induced permeability noise of the magnetic core according to the functional relationship includes: determining a noise term introduced by a temperature variation-induced permeability factor of the magnetic core in the functional relationship between the induced voltage of the coil and the effective permeability of the magnetic core; excluding a negligible term in the noise term introduced by the temperature variation-induced permeability factor of the magnetic core; and obtaining the equivalent voltage noise expression of the temperature variation-induced permeability noise.

As shown in Equation (3), the induced voltage is obtained by summing four parts, which correspond to four terms in the addition operation of Equation (3). A first term represents an original induced voltage of the coil, and each of the remaining three terms may represent a noise term introduced by the temperature variation-induced permeability factor of the magnetic core. The negligible terms introduced by the temperature variation-induced permeability factor of the magnetic core may be excluded from the noise terms, and the equivalent voltage noise expression of the temperature variation-induced permeability noise may be obtained according to a target noise term.

Specifically, the functional relationship in Equation (3) is in the form of a polynomial. Except for the first term which represents the original induced voltage of the coil, the expression of the functional relationship between the induced voltage of the coil and the effective permeability of the magnetic core includes three noise terms introduced by the temperature variation-induced permeability factor of the magnetic core. The three noise terms include a second term

$$NS \vec{{B}_{DC}} \frac{d {μ}_{appDC}}{dt} ,$$

a third term

$$NS \frac{d ( \overline{{B}_{AC}} \times {μ}_{appAC} )}{dt} ,$$

and a fourth term

$$NS \overline{{B}_{DC}} \frac{d {μ}_{appDC}}{dt} .$$

Considering that the AC component B_{AC} of the magnetic flux intensity is far less than the DC component B_{DC} and that the DC component μ_{appDC} of the effective permeability does not change over time, the third term and the fourth term in the noise terms introduced by the temperature variation-induced permeability factor of the magnetic core may be neglected. Let f represents a frequency, the equivalent voltage noise expression of the temperature variation-induced permeability noise of the magnetic core in a frequency domain may be expressed by Equation (4).

$${e}_{TC} ( f ) = \vert {NSB}_{DC} \times 2 π f {μ}_{appAC} ( f ) \vert ( V / \sqrt{Hz} ) \qquad ( 4 )$$

where e_{TC}(f) represents an equivalent voltage noise expression of the TC noise in units of V/\sqrt{Hz}.

According to embodiments of the present disclosure, the key influencing factor of the magnetic core is used to reduce a change in the effective permeability caused by the temperature variation, and may include a material of the magnetic core, a geometric structure of the magnetic core, a heat treatment process of the magnetic core, and the like.

According to embodiments of the present disclosure, the dual-channel composite multi-stage modulation signal-noise separation circuit includes a high-frequency channel and a low-frequency channel, and the noise may be separated from the high-frequency channel and the low-frequency channel, so as to ensure that the inductive magnetic field sensor has a low noise voltage and a low noise current across the entire frequency band.

According to embodiments of the present disclosure, a functional relationship between the induced voltage of the coil and the effective permeability of the magnetic core is determined, an equivalent voltage noise expression of the temperature variation-induced permeability noise of the magnetic core is determined according to the functional relationship, a key influencing factor of the magnetic core is determined according to the equivalent voltage noise expression of the temperature variation-induced permeability noise of the magnetic core, the magnetic core is modified according to the key influencing factor of the magnetic core to optimize the temperature variation-induced permeability noise of the magnetic core, and a dual-channel composite multi-stage modulation signal-noise separation circuit is constructed to optimize the low-frequency band noise and the high-frequency band noise of the inductive magnetic field sensor. As the magnetic core is modified according to the key influencing factor of the magnetic core, the rate of change of the effective permeability of the magnetic core with temperature may be reduced, so that the temperature variation-induced noise of the magnetic core may be reduced. Further, by constructing the dual-channel composite multi-stage modulation signal-noise separation circuit to separate the low-frequency band noise and the high-frequency band noise, the inductive magnetic field sensor may have characteristics of high sensitivity and low noise across a broad band and may be applied in a wider range of application scenarios.

According to embodiments of the present disclosure, by analyzing an influence of the effective permeability of the magnetic core on the induced voltage of the coil through the functional relationship between the induced voltage of the coil and the effective permeability of the magnetic core, it is possible to subsequently optimize the noise from the temperature variation-induced noise of the magnetic core and other sources.

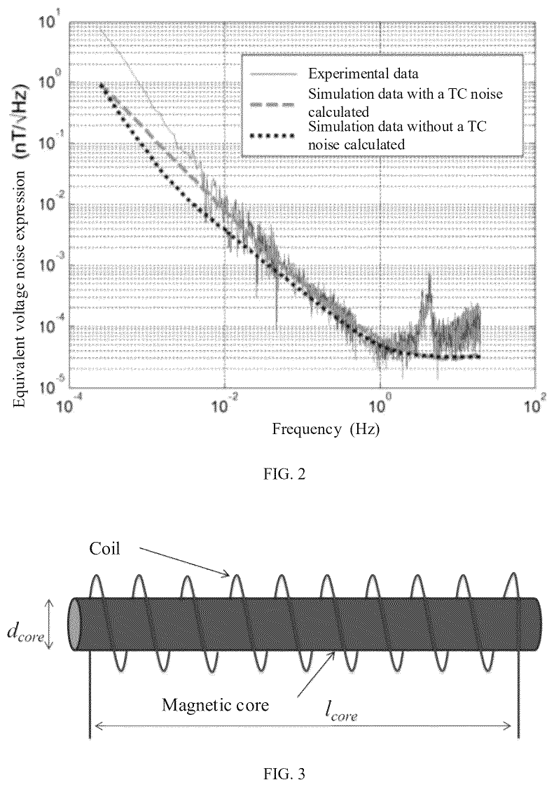

FIG. 2 schematically shows a comparison diagram of noise curves of an inductive magnetic field sensor according to embodiments of the present disclosure.

As shown in FIG. 2, experimental data shows a result of equivalent voltage noise actually measured in a shielded chamber. The recorded temperature variation of the sensor was 0.1° C./4000 s, and a magnetic flux intensity of a DC geomagnetic field in an axial direction of the sensor is 198 nT. By comparing simulation data with the experimental data, it may be observed that the equivalent voltage noise caused by the temperature variation-induced permeability noise of the magnetic core in the frequency domain of the sensor is more obvious in the low-frequency band.

According to embodiments of the present disclosure, the AC component of the effective permeability is determined as the key influencing factor of the magnetic core according to the equivalent voltage noise expression of the temperature variation-induced permeability noise of the magnetic core, and the AC component of the effective permeability reflects a rate of change of magnetic permeability of the magnetic core with temperature.

According to embodiments of the present disclosure, modifying the magnetic core according to the key influencing factor of the magnetic core includes: selecting a magnetic core made of a suitable material according to an application environment of the sensor; performing a vacuum magnetic-field annealing at a set temperature on the magnetic core while maintaining the effective permeability of the magnetic core to adjust an anisotropy of the magnetic core material and reduce internal structural defects, so as to reduce a rate of change of the effective permeability of the magnetic core with temperature; and optimizing a magnetic circuit of the magnetic core by providing flat disk-shaped magnetic flux concentrators at both ends of the magnetic core, where centers of the magnetic flux concentrators are closely attached to both ends of the magnetic core to form a barbell shape as a whole.

According to embodiments of the present disclosure, the effective permeability μₐₚₚ of the magnetic core increases with an increase of an initial permeability μᵣ of the magnetic core material. However, when the μᵣ increases to a certain level, the μₐₚₚ becomes only related to the length-to-diameter ratio of the magnetic core and no longer increase with the μᵣ without limit.

According to embodiments of the present disclosure, under a condition of maintaining the effective permeability of the magnetic core, it is needed to reduce a rate of change of the magnetic core material with temperature through a stress relief, so as to reduce the temperature variation-induced permeability noise of the magnetic core.

According to embodiments of the present disclosure, the magnetic-field annealing may adjust the anisotropy of the magnetic core material and reduce internal structural defects, and the vacuum environment may protect the material from an oxidation during the annealing. The vacuum magnetic-field annealing at an appropriate set temperature may adjust an easy magnetization direction of the soft magnetic material, thereby reducing the rate of change of the magnetic core with temperature. In the vacuum magnetic-field annealing, a magnetic field intensity may range from 0 T to 0.1 T, and an annealing time may range from 1 hour to 24 hours, which may be adjusted according to the practical application and is not limited here.

According to embodiments of the present disclosure, taking a cylindrical magnetic core as an example, a length-to-diameter ratio m may be expressed by Equation (5).

$$m = \frac{{l}_{core}}{{d}_{core}} \qquad ( 5 )$$

where I_{core} represents a length of the magnetic core, and d_{core} represents a diameter of the magnetic core.

FIG. 3 schematically shows a schematic diagram of a long straight cylindrical magnetic core and a coil according to embodiments of the present disclosure.

As shown in FIG. 3, magnetic field lines may converge in the magnetic core, thus significantly enhancing the magnetic flux through a cross-section of the coil. However, the magnetic core has a limited length and is not closed, and the magnetic field lines may diverge at both ends of the magnetic core, which affects a magnetic flux concentrating capability of the magnetic core, i.e., a demagnetization effect occurs. A strength of the demagnetization effect is represented by a demagnetization factor NB, which is determined solely by the shape of the magnetic core and is independent of the magnetic core material.

According to embodiments of the present disclosure, for the long straight cylindrical magnetic core in FIG. 3, a process of accurately estimating the demagnetization factor may be expressed by Equation (6).

$${N}_{B} = \frac{1}{{m}^{2} - 1} \{ \frac{m}{2 {( {m}^{2} - 1 )}^{\frac{1}{2}}} ln ( \frac{m + {( {m}^{2} - 1 )}^{\frac{1}{2}}}{m - {( {m}^{2} - 1 )}^{\frac{1}{2}}} ) - 1 \} \qquad ( 6 )$$

According to embodiments of the present disclosure, for a more slender cylindrical magnetic core, that is, in a case that the length-to-diameter ratio m is greater than 10, a process of simply estimating the demagnetization factor may be expressed by Equation (7).

$${N}_{B} = \frac{1}{{m}^{2}} ( ln 2 m - 1 ) \qquad ( 7 )$$

According to embodiments of the present disclosure, under the action of the demagnetization effect, a relationship between the effective permeability and the initial permeability may be expressed by Equation (8).

$${μ}_{app} = \frac{{μ}_{r}}{1 + {N}_{B} ( {μ}_{r} - 1 )} \qquad ( 8 )$$

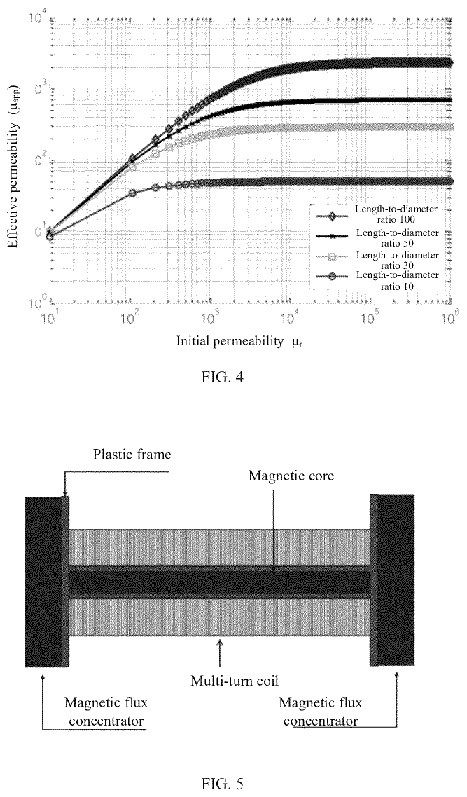

FIG. 4 schematically shows variation curves of effective permeability corresponding to different length-to-diameter ratios of magnetic cores according to embodiments of the present disclosure.

As shown in FIG. 4, in a case of the same initial permeability, the effective permeability of magnetic cores having length-to-diameter ratios of 10, 30, 50 and 100 increases progressively.

According to embodiments of the present disclosure, the length-to-diameter ratio of the magnetic core cannot be increased without limit, because the length of the magnetic core of the inductive magnetic field sensor is restricted by the application scenario and cannot be increased without limit, and also because the cross-section of the magnetic core is restricted by manufacturing processes and cannot be reduced without limit. Further, a reduction of the cross-sectional area may lead to a decrease in an output voltage. Moreover, when the magnetic core is placed in the geomagnetic field, if the μₐₚₚ is too large, the magnetic core may be magnetically saturated by the geomagnetic field, thereby causing a nonlinear saturation distortion to the sensor.

According to embodiments of the present disclosure, assuming that a maximum value of the geomagnetic field is Hₘₐₓ, a saturation magnetic flux of the magnetic core material is Bs, and a tolerable error rate of the inductive magnetic field sensor is δ, then a maximum effective permeability μₐₚₚₘₐₓ of the magnetic core may be expressed by Equation (9).

$${μ}_{appmax} = \frac{{μ}_{r}}{3 \sqrt{( \frac{1}{δ} - 1 ) {( \frac{{π H}_{max} {μ}_{r}}{2 {B}_{s}} )}^{2} - 1}} \qquad ( 9 )$$

According to embodiments of the present disclosure, in a case that the length of the magnetic core remains unchanged, it is possible to provide magnetic flux concentrators to reduce a divergence degree of the magnetic field lines at the ends of the magnetic core, thereby enhancing the magnetic flux concentration effect and improving the effective permeability.

For example, a pair of flat disk-shaped magnetic flux concentrators may be provided to closely attached to both ends of the magnetic core, so that more magnetic field lines may be concentrated inside the magnetic core.

FIG. 5 schematically shows a schematic diagram of a magnetic flux concentrator according to embodiments of the present disclosure.

As shown in FIG. 5, the centers of the magnetic flux concentrators are closely attached to both ends of the magnetic core, forming a barbell shape with the magnetic core.

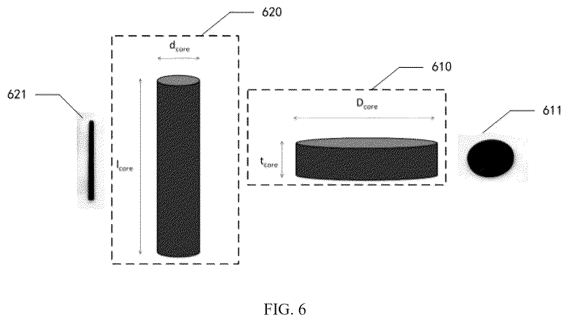

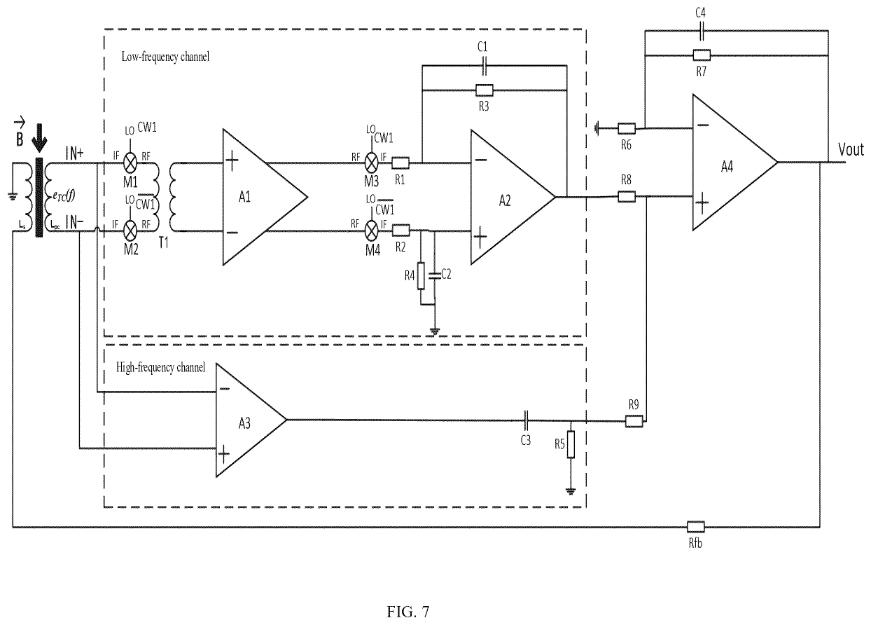

FIG. 6 schematically shows a schematic dimensional diagram of a magnetic flux concentrator and a magnetic core according to embodiments of the present disclosure.

As shown in FIG. 6, a magnetic flux concentrator 610 has a diameter D_{core} and a length t_{core}, a physical representation of the magnetic flux concentrator is denoted by 611, and a physical representation of the magnetic core 620 is denoted by 621.

According to embodiments of the present disclosure, for a magnetic core with a pair of magnetic flux concentrators at both ends, a length-to-diameter ratio m′ may be expressed by Equation (10).

$${m}^{′} = \frac{{l}_{core} + 2 {t}_{core}}{{D}_{core}} \qquad ( 10 )$$

According to embodiments of the present disclosure, Equation (10) may be substituted into the expression of the demagnetization factor to obtain a demagnetization factor N′ in this case, and the effective permeability μₐₚₚ′ in this case may be expressed by Equation (11).

$${{μ}_{app}}^{′} = \frac{{μ}_{r}}{1 + {N}^{′} \times {( \frac{{d}_{core}}{{D}_{core}} )}^{2} ( {μ}_{r} - 1 )} \qquad ( 11 )$$

According to embodiments of the present disclosure, when the diameter of the magnetic core is far less than the diameter of the magnetic flux concentrator, the magnetic flux concentrator may exert a significant effect, that is, it may significantly increase the effective permeability of the magnetic core. Taking a magnetic core with d_{core} of 10 mm, I_{core} of 200 mm, D_{core} of 110 mm, and t_{core} of 10 mm as an example, the μₐₚₚ of the magnetic core is 145 when the magnetic flux concentrators are not provided, and the μₐₚₚ′ of the magnetic core is 634 when the magnetic flux concentrators are provided. Thus, the magnetic flux concentrators may greatly enhance the effective permeability of the magnetic core.

According to embodiments of the present disclosure, the vacuum magnetic-field annealing process may be performed to reduce the temperature variation-induced permeability noise of the magnetic core, and the magnetic flux concentrators may be provided to change the shape of the magnetic core, thereby reducing the influence of the demagnetization effect on the effective permeability and improving the sensitivity of the inductive magnetic field sensor.

According to embodiments of the present disclosure, constructing the dual-channel composite multi-stage modulation signal-noise separation circuit to optimize the low-frequency band noise and the high-frequency band noise of the sensor includes: constructing a low-frequency channel to modulate a low-frequency component of a magnetic field signal to a frequency band away from a 1/f noise of an amplifier in the low-frequency channel, amplify the modulated magnetic field signal, demodulate the amplified magnetic field signal back to a low-frequency band, and filter the demodulated magnetic field signal to achieve a signal-noise separation, so as to obtain the low-frequency component of the magnetic field signal; constructing a high-frequency channel to amplify the magnetic field signal and filter out a 1/f noise of an amplifier in the high-frequency channel, so as to obtain a high-frequency component of the magnetic field signal; and constructing a low-high frequency channel composite unit to integrate the low-frequency component and the high-frequency component of the magnetic field signal, so as to optimize the low-frequency band noise and the high-frequency band noise of the sensor.

According to embodiments of the present disclosure, the low-frequency channel may modulate and amplify the low-frequency component of the magnetic field signal so that the low-frequency component is amplified without being affected by the 1/f noise, then demodulate the magnetic field signal back to the original low-frequency band, and then filter out a high-frequency noise using a filter to achieve a signal-noise separation, thereby obtaining a clear low-frequency component of the magnetic field signal.

According to embodiments of the present disclosure, the high-frequency component is amplified directly through the high-frequency channel, and the 1/f noise of the amplifier is filtered out.

According to embodiments of the present disclosure, the low-frequency component and the high-frequency component of the magnetic field signal are integrated to obtain a complete magnetic field signal, thereby effectively reducing the low-frequency band noise and the high-frequency band noise of the sensor.

FIG. 7 schematically shows a schematic circuit diagram of an inductive magnetic field sensor with broadband noise optimization according to embodiments of the present disclosure.

Another embodiment of the present disclosure, as shown in FIG. 7, discloses an inductive magnetic field sensor with broadband noise optimization, including: a magnetic core, where the magnetic core has undergone vacuum magnetic-field annealing at a set temperature to adjust an anisotropy of a magnetic core material and reduce internal structural defects so as to reduce a rate of change of effective permeability of the magnetic core with temperature; a coil wound around a periphery of the magnetic core; and a dual-channel composite multi-stage modulation signal-noise separation circuit connected to the coil, including: a low-frequency channel configured to modulate a low-frequency component of a magnetic field signal to a frequency band away from a 1/f noise of an amplifier in the low-frequency channel, amplify the modulated magnetic field signal, demodulate the amplified magnetic field signal back to a low-frequency band and filter the demodulated magnetic field signal to achieve a signal-noise separation, so as to obtain the low-frequency component of the magnetic field signal; a high-frequency channel arranged in parallel with the low-frequency channel, where the high-frequency channel is configured to amplify the magnetic field signal and filter out a 1/f noise of an amplifier in the high-frequency channel, so as to obtain a high-frequency component of the magnetic field signal; and a low-high frequency channel composite unit connected to the low-frequency channel and the high-frequency channel, where the low-high frequency channel composite unit is configured to integrate the low-frequency component and the high-frequency component of the magnetic field signal, so as to optimize a low-frequency band noise and a high-frequency band noise of the sensor.

It should be noted that a section of the inductive magnetic field sensor with broadband noise optimization in embodiments of the present disclosure corresponds to a section of the method for optimizing a broadband noise of an inductive magnetic field sensor in embodiments of the present disclosure. For the specific description of the sensor, reference may be made to the section of the method for optimizing the noise, which will not be repeated here.

According to embodiments of the present disclosure, the vacuum magnetic-field annealing at a set temperature is performed to adjust the anisotropy of the magnetic core material and reduce internal structural defects, thereby reducing the rate of change of the effective permeability of the magnetic core with temperature and then reducing the temperature variation-induced permeability noise of the magnetic core. The low-frequency channel of the dual-channel composite multi-stage modulation signal-noise separation circuit may modulate the low-frequency component of the magnetic field signal to a frequency band away from the 1/f noise of the amplifier in the low-frequency channel, amplify the modulated magnetic field signal, demodulate the amplified magnetic field signal back to the low-frequency band, and filter the demodulated magnetic field signal to achieve signal-noise separation. The high-frequency channel may amplify the magnetic field signal and filter out the 1/f noise of the amplifier in the high-frequency channel to obtain the high-frequency component of the magnetic field signal. The low-high frequency channel composite unit may integrate the low-frequency component and the high-frequency component of the magnetic field signal to provide a complete magnetic signal. In this way, the low-frequency band noise and the high-frequency band noise may be reduced, the application range of the sensor may be expanded, and the sensor may be applied to a wider range of magnetic field measurement scenarios.

According to embodiments of the present disclosure, the low-frequency channel includes a first modulation unit, a transformer, a first amplifier, a second modulation unit and a low-pass filter circuit unit. The first modulation unit is configured to modulate a low-frequency component of a received magnetic field signal to a frequency band away from the 1/f noise of the first amplifier; the transformer is configured to passively amplify the signal modulated by the first modulation unit; the first amplifier is configured to further amplify the signal amplified by the transformer; the second modulation unit is configured to demodulate the amplified magnetic field signal back to the low-frequency band and modulate the 1/f noise and a bias of the first amplifier to a high-frequency band; and the low-pass filter circuit unit is configured to filter out a high-frequency band noise interference. The high-frequency channel includes a high-pass filter composed of a third amplifier, a capacitor and a resistor connected in sequence, which is used to amplify the magnetic field signal and filter out the 1/f noise of the amplifier in the high-frequency channel, thereby obtaining the high-frequency component of the magnetic field signal. The low-high frequency channel composite unit includes a fourth amplifier, a capacitor and a plurality of resistors. A negative input terminal of the fourth amplifier is connected to a resistor, a capacitor and a resistor are connected in parallel between the negative input terminal and an output terminal of the fourth amplifier, and a positive input terminal of the fourth amplifier is connected to an output terminal of the low-frequency channel and an output terminal of the high-frequency channel through a resistor, so as to enable the low-high frequency channel composite unit to integrate the low-frequency component and the high-frequency component of the magnetic field signal to optimize the low-frequency band noise and the high-frequency band noise of the sensor.

According to embodiments of the present disclosure, as shown in FIG. 7, the coil is connected to the dual-channel composite multi-stage modulation signal-noise separation circuit, Lₛ represents a feedback coil, and L_{pc} represents a main coil. The first modulation unit includes a first modulator M1 and a second modulator M2. The received magnetic field signal is input via IN+ at one end, and input via IN− at the other end. The first modulator M1 has an IF pin connected to IN+, and an LO pin connected to a first modulation signal CW1. The second modulator M2 has an IF pin connected to IN−, and an LO pin connected to a modulation signal C̅W̅1̅. CW1 and C̅W̅1̅ have the same frequency and amplitude but opposite phases. An RF pin of the first modulator M1 and an RF pin the second modulator M2 are connected to the input terminal of the transformer T1, and the output terminal of the transformer T1 is connected to the first amplifier A1. The transformer T1 may passively amplify the signal modulated by the first modulation unit, and the first amplifier A1 may further amplify the signal amplified by the transformer. The second modulation unit includes a first demodulator M3 and a second demodulator M4. The first amplifier A1 has a positive output terminal connected to an RF pin of the first demodulator M3, and a negative output terminal connected to an RF pin of the second demodulator M4. The first demodulator M3 has an LO pin connected to a demodulation signal CW1, and an IF pin connected to the resistor R1. The second demodulator M4 has an LO pin connected to a demodulation signal C̅W̅1̅, and an IF pin connected to the resistor R2. The low-pass filter circuit unit includes a second amplifier A2, a resistor R1, a resistor R3, a resistor R4, a capacitor C1, a capacitor C2, and a resistor R4. The resistor R3 and the capacitor C1 are arranged in parallel between the negative input terminal and the output terminal of the second amplifier A2. The positive input terminal of the second amplifier A2 is connected to the resistor R2. The capacitor C2 and the resistor R4 are connected in parallel, with one side connected between the positive input terminal of the second amplifier A2 and the resistor R2, and the other side grounded. The second modulation unit may demodulate the amplified magnetic field signal back to the low-frequency band and modulate the bias and the 1/f noise of the first amplifier A1 to the high-frequency band, thereby achieving the signal-noise separation. The low-pass filter circuit unit is configured to filter out a high-frequency band noise interference.

According to embodiments of the present disclosure, as shown in FIG. 7, the high-frequency channel includes a third amplifier A3, a capacitor C3, and a resistor R5. The third amplifier A3 may amplify the magnetic field signal. The capacitor C3 and the resistor R5 form a high-pass filter, which is connected to an output terminal of the third amplifier A3 to filter out a low-frequency 1/f noise of the third amplifier A3, etc. and retain only the high-frequency component of the magnetic field signal. A negative (−) input terminal of the third amplifier A3 is connected to IN+, and a positive (+) input terminal of the third amplifier A3 is connected to IN−. The output terminal of the third amplifier A3 is connected to one end of the capacitor C3, and the other end of the capacitor C3 is connected to the resistor R5 and the resistor R9. The other end of the resistor R5 is grounded.

According to embodiments of the present disclosure, as shown in FIG. 7, the low-high frequency channel composite unit includes a fourth amplifier A4, a capacitor C4, and a plurality of resistors (resistor R6, resistor R7, resistor R8, resistor R9). The low-frequency channel signal and the high-frequency channel signal are integrated based on a principle of a summation circuit to achieve a wideband signal amplification. A positive input terminal of the fourth amplifier A4 is connected to the output terminal of the high-frequency channel and the output terminal of the low-frequency channel through the resistor R8, ad the other end of the resistor R8 is connected to the positive (+) input terminal of the fourth amplifier A4. The resistor R9 has one end connected to the output terminal of the high-frequency channel, and the other end connected to the positive (+) input terminal of the fourth amplifier A4. The negative (−) input terminal of the fourth amplifier is connected to the resistor R6, the resistor R7 and the capacitor C4. An output terminal of the fourth amplifier A4 is connected to a circuit output signal Vout, which is connected to the feedback coil Lₛ through a feedback resistor Rfb to introduce a feedback current into the feedback coil of the magnetic field sensor, thereby forming a closed-loop feedback structure.

According to the method for optimizing a broadband noise of an inductive magnetic field sensor as well as the magnetic field sensor of the present disclosure, it is possible to break through a restriction of the inherent 1/f noise in the low-frequency band based on the dual-channel composite multi-stage modulation signal-noise separation technology, and it is possible to break through a principle restriction of Faraday's law of electromagnetic induction in a limited space and a restriction of the demagnetization coefficient and the effective permeability through a magnetic circuit distribution control technology by using a method for suppressing a demagnetization effect of an open-loop magnetic circuit, thereby enabling accurate detection of femtotesla-level magnetic field signals across both low-frequency band and high-frequency band from 10⁻⁸ Hz to 10⁶ Hz, and achieving an effective noise suppression over the entire frequency band.

Those skilled in the art may understand that the features recited in embodiments of the present disclosure may be combined and/or integrated in various ways, even if such combinations or integrations are not explicitly described in the present disclosure. In particular, the features recited in embodiments of the present disclosure may be combined and/or integrated in various ways without departing from the spirit and teachings of the present disclosure. All these combinations and/or integrations fall within the scope of the present disclosure.

Embodiments of the present disclosure have been described above. However, these embodiments are for illustrative purposes only and are not intended to limit the scope of the present disclosure. Although the embodiments have been described separately above, this does not mean that measures in the embodiments cannot be used in combination advantageously. Various substitutions and modifications may be made by those skilled in the art without departing from the scope of the present disclosure, and these substitutions and modifications should all fall within the scope of the present disclosure.

What is claimed is:

1. A method for optimizing a broadband noise of an inductive magnetic field sensor, comprising:
determining a functional relationship between an induced voltage of a coil of the inductive magnetic field sensor and an effective permeability of a magnetic core of the inductive magnetic field sensor;
determining an equivalent voltage noise expression of a temperature variation-induced permeability noise of the magnetic core according to the functional relationship;
determining a key influencing factor of the magnetic core according to the equivalent voltage noise expression of the temperature variation-induced permeability noise of the magnetic core;
modifying the magnetic core according to the key influencing factor of the magnetic core to optimize the temperature variation-induced permeability noise of the magnetic core; and
constructing a dual-channel composite multi-stage modulation signal-noise separation circuit to optimize a low-frequency band noise and a high-frequency band noise of the inductive magnetic field sensor,
wherein the determining an equivalent voltage noise expression of a temperature variation-induced permeability noise of the magnetic core according to the functional relationship comprises: determining a noise term introduced by a temperature variation-induced permeability factor of the magnetic core in the functional relationship between the induced voltage of the coil and the effective permeability of the magnetic core; excluding a negligible term in the noise term introduced by the temperature variation-induced permeability factor of the magnetic core; and obtaining the equivalent voltage noise expression of the temperature variation-induced permeability noise of the magnetic core,
wherein the functional relationship between the induced voltage of the coil and the effective permeability of the magnetic core of the inductive magnetic field sensor is expressed as:
$$\overline{e ( t )} = - [ NS {μ}_{appDC} \frac{d \overline{{B}_{AC}}}{dt} + \text{} NS \overline{{B}_{DC}} \frac{d {μ}_{appAC}}{dt} + NS \frac{d ( \overline{{B}_{AC}} \times {μ}_{appAC} )}{dt} + NS \overline{{B}_{DC}} \frac{d {μ}_{appDC}}{dt} ] ,$$
wherein μ_{appDC} represents a direct current component of the effective permeability, μ_{appAC} represents an alternating current component of the effective permeability, B_{DC} represents a direct current component of a magnetic flux intensity B, B_{AC} represents an alternating current component of the magnetic flux intensity B, N represents a number of turns of the coil, S represents a cross-sectional area of the coil and the magnetic core, and μₐₚₚ represents the effective permeability of the magnetic core,
wherein the noise terms introduced by the temperature variation-induced permeability factor of the magnetic core in the expression of the functional relationship between the induced voltage of the coil and the effective permeability of the magnetic core comprise a second term
$$NS \overline{{B}_{DC}} \frac{d {μ}_{appAC}}{dt} ,$$
a third term
$$NS \frac{d ( \overline{{B}_{AC}} \times {μ}_{appAC} )}{dt} ,$$
and a fourth term
$$NS \overline{{B}_{DC}} \frac{d {μ}_{appDC}}{dt} ,$$
the alternating current component B_{AC} of the magnetic flux intensity is far less than the direct current component B_{DC} of the magnetic flux intensity and the direct current component μ_{appDC} of the effective permeability does not change over time so that the third term and the fourth term in the noise terms introduced by the temperature variation-induced permeability factor of the magnetic core are the negligible terms, and the equivalent voltage noise expression of the temperature variation-induced permeability noise of the magnetic core in a frequency domain is expressed as:
$${e}_{TC} ( f ) = \vert {NSB}_{DC} \times 2 π f {μ}_{appAC} ( f ) \vert ( V / \sqrt{Hz} ) ,$$
where f represents a frequency,
wherein the alternating current component of the effective permeability is determined as the key influencing factor of the magnetic core according to the equivalent voltage noise expression of the temperature variation-induced permeability noise of the magnetic core, and the alternating current component of the effective permeability reflects a rate of change of magnetic permeability of the magnetic core with temperature,
wherein the modifying the magnetic core according to the key influencing factor of the magnetic core comprises: selecting a magnetic core made of a suitable material according to an application environment of the inductive magnetic field sensor; performing a vacuum magnetic-field annealing at a set temperature on the magnetic core while maintaining the effective permeability of the magnetic core to adjust an anisotropy of the magnetic core material and reduce internal structural defects, so as to reduce a rate of change of effective permeability of the magnetic core with temperature; and optimizing a magnetic circuit of the magnetic core by providing flat disk-shaped magnetic flux concentrators at both ends of the magnetic core, wherein centers of the magnetic flux concentrators are closely attached to both ends of the magnetic core to form a barbell shape as a whole.

2. The method according to claim 1, wherein the determining a functional relationship between an induced voltage of a coil and an effective permeability of a magnetic core of the inductive magnetic field sensor comprises:
determining a functional relationship between the induced voltage of the coil and the effective permeability of the magnetic core in a time domain in a non-constant temperature environment, wherein a relative permeability of a magnetic core material changes slowly with temperature so that the effective permeability of the magnetic core changes with temperature, and the effective permeability of the magnetic core comprises a direct current component and an alternating current component.

3. The method according to claim 1, wherein the constructing a dual-channel composite multi-stage modulation signal-noise separation circuit to optimize a low-frequency band noise and a high-frequency band noise of the inductive magnetic field sensor comprises:
constructing a low-frequency channel to modulate a low-frequency component of a magnetic field signal to a frequency band away from a 1/f noise of an amplifier in the low-frequency channel, amplify the modulated magnetic field signal, demodulate the amplified magnetic field signal back to a low-frequency band and filter the demodulated magnetic field signal to achieve a signal-noise separation, so as to obtain the low-frequency component of the magnetic field signal;
constructing a high-frequency channel to amplify the magnetic field signal and filter out a 1/f noise of an amplifier in the high-frequency channel, so as to obtain a high-frequency component of the magnetic field signal; and
constructing a low-high frequency channel composite unit to integrate the low-frequency component and the high-frequency component of the magnetic field signal, so as to optimize the low-frequency band noise and the high-frequency band noise of the inductive magnetic field sensor.

4. An inductive magnetic field sensor with broadband noise optimization, comprising:
a magnetic core, wherein the magnetic core has undergone vacuum magnetic-field annealing at a set temperature to adjust an anisotropy of a magnetic core material and reduce internal structural defects so as to reduce a rate of change of effective permeability of the magnetic core with temperature;
a coil wound around a periphery of the magnetic core; and
a dual-channel composite multi-stage modulation signal-noise separation circuit connected to the coil, comprising:
a low-frequency channel configured to modulate a low-frequency component of a magnetic field signal to a frequency band away from a 1/f noise of an amplifier in the low-frequency channel, amplify the modulated low-frequency component, demodulate the amplified low-frequency component back to a low-frequency band and filter the demodulated low-frequency component to achieve a signal-noise separation, so as to obtain the low-frequency component of the magnetic field signal;
a high-frequency channel arranged in parallel with the low-frequency channel, wherein the high-frequency channel is configured to amplify the magnetic field signal and filter out a 1/f noise of an amplifier in the high-frequency channel, so as to obtain a high-frequency component of the magnetic field signal; and
a low-high frequency channel composite unit connected to the low-frequency channel and the high-frequency channel, wherein the low-high frequency channel composite unit is configured to integrate the low-frequency component and the high-frequency component of the magnetic field signal, so as to optimize a low-frequency band noise and a high-frequency band noise of the inductive magnetic field sensor.

5. The inductive magnetic field sensor according to claim 4, wherein the low-frequency channel comprises a first modulation unit, a transformer, a first amplifier, a second modulation unit and a low-pass filter circuit unit, wherein:
the first modulation unit is configured to modulate a low-frequency component of a received magnetic field signal to a frequency band away from a 1/f noise of the first amplifier;
the transformer is configured to passively amplify the magnetic field signal modulated by the first modulation unit;
the first amplifier is configured to further amplify the magnetic field signal amplified by the transformer;
the second modulation unit is configured to demodulate the amplified magnetic field signal back to a low-frequency band and modulate the 1/f noise and a bias of the first amplifier to a high-frequency band; and
the low-pass filter circuit unit is configured to filter out a high-frequency band noise interference;
wherein the high-frequency channel comprises a high-pass filter composed of a third amplifier, a capacitor and a resistor connected in sequence, and the high-pass filter is configured to amplify the magnetic field signal and filter out a 1/f noise of the third amplifier in the high-frequency channel to obtain the high-frequency component of the magnetic field signal; and
wherein the low-high frequency channel composite unit comprises a fourth amplifier, a capacitor and a plurality of resistors, a negative input terminal of the fourth amplifier is connected to a resistor, the capacitor and a resistor are connected in parallel between the negative input terminal and an output terminal of the fourth amplifier, and a positive input terminal of the fourth amplifier is connected to an output terminal of the low-frequency channel and an output terminal of the high-frequency channel through a resistor, so as to enable the low-high frequency channel composite unit to integrate the low-frequency component and the high-frequency component of the magnetic field signal to optimize the low-frequency band noise and the high-frequency band noise of the inductive magnetic field sensor.
